(19) United States
(12) Patent Application Publication
(10) Pub. No.: US 2006/0092689 A1
(43) Pub. Date: May 4, 2006

(54) Reference current source for current sense amplifier and programmable resistor configured with magnetic tunnel junction cells

(76) Inventors: Daniel Braun, Paris (FR); Ulrich Klostermann, Fontainebleau (FR)

Correspondence Address: SLATER & MATSIL LLP, 17950 PRESTON ROAD, SUITE 1000, DALLAS, TX, 75252, US

(21) Appl. No.: 10/982,026

(22) Filed: Nov. 4, 2004

(51) Int. Cl. G11C 11/00

(52) U.S. Cl. 365/158

(57) ABSTRACT

A reference current source for a magnetic memory device is preferably configured with magnetic tunnel junction cells and includes more than four reference magnetic memory cells to improve reliability of the magnetic memory device and to reduce sensitivity at a device level to individual cell failures. The reference current source includes a large number of magnetic memory cells coupled in an array, and a current source provides a reference current dependent on the array resistance. In another embodiment a large number of magnetic memory cells are coupled to current sources that are summed and scaled to produce a reference current source. A current comparator senses the unknown state of a magnetic memory cell. In a further embodiment, an array of magnetic memory cells is configured to provide a non-volatile, adjustable resistance. In a further embodiment, the array of magnetic memory cells is configured with a tap to provide a non-volatile, adjustable potentiometer.

### CROSS-REFERENCE TO RELATED APPLICATIONS

This application relates to co-pending and commonly assigned patent applications which are hereby incorporated herein by reference:

| Patent or | | | Attorney |
|---|---|---|---|
| Ser. No. | Filing Date | Issue Date | Docket No. |
| 10/326,367 | Dec. 20, 2002 | | 2002 P 50075 |
| 10/937,155 | Sep. 7, 2004 | | 2004 P 50911 |
| 10/925,487 | Aug. 25, 2004 | | 2003 P 52584 |
| <xxx> | | | 2004 P 51925 |

### TECHNICAL FIELD

Embodiments of the present invention relate generally to using multiple magnetic tunnel junction cells to improve the reliability of semiconductor memory devices, and more particularly, to reference current sources for sensing circuits for determining the resistive state of memory cells, and, further, to their use for configuring programmable, non-volatile resistors.

### BACKGROUND

Semiconductors are used in integrated circuits for electronic applications, including radios, televisions, cell phones, and personal computing devices, as examples. One type of semiconductor device is a semiconductor storage device, such as a dynamic random access memory (DRAM) and flash memory, which uses a charge to store information.

Various memory types are in common use to store digitally a substantial amount of data. DRAMs have moderate cost, are very fast and can have access times on the order of 30 ns nanoseconds, but lose the stored data upon loss of electrical power, i.e., they are “volatile.” “Flash” memories are non-volatile, and the time required to store the first information bit in the memory is long (ms-s). Hard disk drives are substantially lower in cost than DRAMs, are non-volatile, but have access times generally greater than a millisecond. Further application considerations for each technology include limitations on the number of times a memory cell can be written or read before it deteriorates, how long it reliably retains data, its data storage density, how much energy it consumes, the need for integral mechanical devices, and the complexity and expense of associated circuitry. Considering these limitations, there is now no ideal technology for general applications. Magnetic random access memory (MRAM) as described below appears to have properties that positions it well for widely accepted digital memory applications, overcoming many of these limitations.

Spin electronics, which combines semiconductor technology and magnetics, is a relatively recent development in semiconductor memory devices. The spin of an electron, rather than the charge, is used to indicate the presence of a logic “1” or “0”. One such spin electronic device is a resistive memory device referred to as a magnetic random access memory, which includes conductive lines positioned perpendicular to one another in different metal layers, the conductive lines sandwiching a magnetic stack which functions as a memory cell. The place where the conductive lines intersect is called a cross-point. A current flowing through one of the conductive lines generates a magnetic field around the conductive line and orients the magnetic polarity of one layer of the magnetic stack. A current flowing through the other conductive line induces a superimposed magnetic field and can partially turn the magnetic polarity, also. Digital information, represented as a “0” or “1”, is storable in the alignment of magnetic moments in the magnetic stack. The resistance of the magnetic stack depends on the moment's alignment. The stored state is read from the magnetic stack by detecting the component's resistive state. An array of memory cells may be constructed by placing the conductive lines in a matrix structure having rows and columns, with the magnetic stack being placed at the intersection of the conductive lines. Rather than storing digital information, an array of such magnetically programmable resistive devices can alternatively be configured to provide an adjustable resistance between at least two nodes.

The devices described herein with a resistance dependent on a programmed state of a magnetic layer are preferably based on the tunneling magnetoresistance effect (TMR), but, alternatively, may be based on other magnetic-orientation dependent resistance effects such as the giant magnetoresistance effect (GMR) or other magnetic-orientation dependent resistance effects relying on the electron charge and its magnetic moment. The reference-current sourcing and programmable resistance devices described herein will generally be described as TMR devices with a resistance dependent on its programmed magnetic state, but other devices based on the GMR or other effects wherein a resistance is dependent on its magnetically programmed state may be readily substituted for the TMR devices within the broad scope of the present invention.

A key advantage of MRAMs compared to traditional semiconductor memory devices, such as DRAMs, is that MRAMs are non-volatile upon removal of electrical power. This is advantageous because a personal computer (PC) utilizing MRAMs could be designed without a long “boot-up” time as with conventional PCs that utilize DRAMs, as an example.

FIG. 1 illustrates a magnetic tunnel junction (MTJ) stack that comprises a resistive or magnetic memory cell. The terms “memory cell,” “MTJ cell,” and “MTJ stack” are used interchangeably herein and refer to the MTJ shown in FIG. 1. The MTJ comprises two ferromagnetic layers M1 and M2 that are separated by a tunnel layer TL. The MTJ stack is positioned at the cross-point of two conductors, referred to as a wordline WL and a bitline BL. One magnetic layer M1 is referred to as a free layer or a storage layer, and the other magnetic layer M2 is referred to as a fixed layer or a reference layer. Two publications describing the art of MRAMs are S. Tehrani, et al., “Recent Developments in Magnetic Tunnel Junction MRAM,” IEEE Trans. on Magnetics. Vol. 36 Issue 5, September 2000, pp. 2752-2757, and J. DeBrosse, A. Bette et al., “A High Speed 128-kb MRAM Core for Future Universal Memory Applications,” IEEE Journal of Solid State Circuits, Vol. 39, Issue 4, April 2004, pp. 678-683. The magnetic orientation of the free layer M1 can be changed by the superposition of the magnetic fields caused by programming current I_{BL} that is run through the bitline BL and the programming current I_{WL} that is run through the wordline WL. A bit, e.g., a “0” or “1”, may be stored in the MTJ stack by changing the orientation of the free magnetic layer relative to the fixed magnetic layer. If both magnetic layers M1 and M2 have the same orientation, the MTJ stack has a lower resistance RC. The resistance RC is higher if the magnetic layers have opposite magnetic orientations.

A free layer may be formed as a soft ferromagnetic layer or, alternatively, may be configured as a stack of more than one ferromagnetic layer, each ferromagnetic layer separated by an antiferromagnetic coupling spacer layer. Such an arrangement is referred to as a synthetic antiferromagnetic layer and is described in the publication M. Durlam, et al., A 0.18 um 4 Mb Toggling MRAM, IEDM 2003. In this publication, the alternative to configure the free layer as a synthetic antiferromagnetic layer is described.

FIG. 2 illustrates a memory cell of an MRAM memory device 10 having a select transistor X1. In some MRAM memory array designs, the MTJ stack is combined with a select transistor X1, as shown in FIG. 2, which is a cross-sectional view of a 1T1MTJ design (one transistor and one MTJ stack). The 1T1MTJ design uses the select transistor X1 for fast access of the MTJ during a read operation. A schematic diagram of the MTJ stack and select transistor X1 is shown in FIG. 3. A bitline BL is coupled to one side of the MTJ stack, and the other side of the MTJ stack is coupled to the drain D of the select transistor X1 by metal layer MX, via VX, and a plurality of other metal and via layers, as shown. The source S of the transistor X1 is coupled to ground (GND). X1 may comprise two parallel transistors that function as one transistor, as shown in FIG. 2. Alternatively, X1 may comprise a single transistor, for example. The gate G of the transistor X1 is coupled to a read wordline (RWL), shown in phantom, that is preferably positioned in a different direction than, e.g., perpendicular to, the bitline BL direction.

The select transistor X1 is used to access the memory cell's MTJ. In a read (RD) operation during current sensing, a constant voltage is applied at the bitline BL. The select transistor X1 is switched on, e.g., by applying a voltage to the gate G by the read wordline RWL, and current then flows through the bitline BL, the magnetic tunnel junction MTJ, over the MX layer, down the metal and via stack, through the transistor drain D, and through the transistor X1 to ground GND. This current is then measured and is used to determine the resistance of the MTJ, thus determining the programming state of the MTJ. To read another cell in the array, the transistor X1 is switched off, and the select transistor of the other cell is switched on.

The programming or write operation is accomplished by programming the MTJ at the cross-points of the bitline BL and programming line or write wordline WWL using selective programming currents. For example, a first programming current IBL passed through the bitline BL causes a first magnetic field component in the MTJ stack. A second magnetic field component is created by a second programming current IWL that is passed through the write wordline WWL, which may run in the same direction as the read wordline RWL of the memory cell, for example. The superposition of the two magnetic fields at the MTJ produced by programming currents IBL and IWL causes the MTJ stack to be programmed. To program a particular memory cell in an array, typically a programming current is run through the write wordline WWL, which creates a magnetic field at all cells along that particular write wordline WWL. Then, a current is run through one of the bitlines, and the superimposed magnetic fields switch only the MTJ stack at the cross-point of the write wordline WWL and the selected bitline BL.

The resistance difference between programmed and unprogrammed MRAM cells is relatively small. For example, the MTJ resistance may be in the order of a 10 k ohm junction, and there may be a change typically of about 20% in MTJ resistance when the free layer magnetizing direction is reversed at the MTJ, but can be as high as 70% or even higher. This changes the sensed value, e.g., from 10 k ohms to 12 k ohms. The MTJ resistance can be in the higher or lower range, depending on the particular material compositions, but may also be influenced by geometry and dimensions of the junction. The percentage change of resistance of GMR structures is usually lower, often in the 5-20% range. Additionally, MTJs can be arranged in circuit configurations such as bridges wherein a state of balance or unbalance can be employed to obtain a substantial change in an operating condition. For other memory devices such as flash memory cells or static random access memory (SRAM) cells, there is a larger resistance difference between programmed and unprogrammed memory cells than in MRAMs. For example, if a flash cell is activated, the “on” resistance is about 5 k ohms, and the “off” resistance is substantially infinite. While other types of memory cells substantially completely switch on or off, an MRAM cell only has a small change in the resistance value upon programming. This makes MRAM cell state sensing more difficult, especially for a very rapid current sensing process that may be required for a high-speed memory.

Either current sensing or voltage sensing of MTJ resistance can be used to detect the state of memory cells. DRAMs usually are sensed using voltage sensing, for example. In voltage sensing, the bitline is precharged, e.g., to 1 volt, with the memory cell not activated. When the memory cell is activated, the memory cell charges or discharges the bitline and changes the voltage of the bitline. However, in some types of memory cells, the memory cell is small, and the bitline length may be long, e.g., may extend the entire width of the chip. The memory cell may not be able to provide enough cell current to discharge or charge a large bitline capacity within a required time. This results in an excessive amount of time being required to read the memory cells. Therefore, voltage sensing is not a preferred choice of sensing scheme for some memory devices, such as MRAM devices, because of the need to alter charge in a parasitic capacitance by a changing voltage.

Current sensing may be used to detect a resistance change of resistive memory cells. Current sensing is the desired method of sensing the state of MRAM cells, for example. In current sensing, a voltage is applied to the bitline, and the bitline voltage is kept constant with a sense amplifier. The cell current is directly measured, with the cell current being dependent on the resistance of the memory cell being read. The use of current sensing reduces the capacitive load problem from long bitlines that may occur in voltage sensing because the voltage of the sensed lines is held constant, thereby avoiding altering charge in the different interconnection capacitances of different memory cells.

In MRAM device current sensing, a constant voltage is applied to the bitline, generally as a source follower, and the current change at the bitline due to the resistance change of the magnetic tunnel junction is measured. However, because the resistance difference between a programmed and an unprogrammed cell is small in MRAM memory cells, the current difference sensed is also smaller than the current change from a flash or an SRAM (static RAM) cell, for example.

Because the difference in resistance of a programmed and unprogrammed MRAM cell may be small, on the order of 20% as described above, it is critical for reliably reading the stored data that an accurate reference current be sourced midway between a programmed and an unprogrammed MRAM cell current, i.e., midway between the current in an MRAM cell programmed to store a logic 1 or a logic 0. A technique for creating an accurate midway reference current is to average the current of a programmed and unprogrammed MRAM cell. However, recognizing that the resistance of a programmed or unprogrammed MRAM cell, being a tunneling device, depends on the applied cell voltage, and that the resistance ratio of a programmed or unprogrammed cell decreases as the applied voltage is increased, it is important that careful consideration be given to MTJ cell voltage when an average cell current is sourced. Moreover, fluctuations of cell parameters that occur in device fabrication as a consequence of the variability of ordinary manufacturing processes contribute adversely to reliability and data accuracy issues associated with producing an economical MRAM end product.

A further consideration of MRAM reliability issues is the consequence of a failure or parameter drift in the reference current generation process. Portions of memory with demonstrable individual cell failures can be isolated by system software, thus preserving operation of those portions of memory that are still useful. For an ordinary memory device, a self-check of memory performance can be made at system start-up, or even from time to time during system operation. For example, a typical PC (personal computer) usually does a RAM memory check during the boot process, and the hard disk can be scanned under user control with operating system software for surface defects. However, a failure in the reference current generation process, even a moderate shift in the reference current from a required average value, renders an entire associated portion of an MRAM device inoperable.

In related and other applications of semiconductor devices it is frequently necessary to provide a resistor whose value must be trimmed or a potentiometer tap adjusted to a desired value in the late stages of manufacture, or even afterwards in an end-user's application, to provide a specified characteristic of an electronic device. Examples of resistors in applications requiring a trimmable resistance include, without limitation, a voltage divider configured to control the output voltage or over-current setting of a power supply, a resistor controlling a reference voltage source, a digital-to-analog converter configured with a resistor to calibrate or otherwise adjust the voltage conversion process, and numerous other applications that require a resistance adjustment to achieve a specified circuit characteristic. In some applications, including MRAM devices, there may be numerous reference voltages and currents that must be adjusted. It is highly desirable that the resistance adjustment mechanism be integrated onto the chip that includes the underlying function such as a digital memory, an op-amp, or a digital-to-analog converter to keep costs low and sizes small. Alternatively, the adjustable resistor or tap setting may be formed on a separate chip.

Trimmable resistors have been implemented in the past with mechanical potentiometers or rheostats or with switches (such as DIP switches) or clearable fuses that select a series-parallel combination of discrete resistors to provide the necessary resistance adjustment. Trimmable resistors generally must retain the adjusted value over time and independently of the intermittent application of power to the circuit, i.e., the trimmed resistance value must be stable as well as non-volatile after removal of circuit power. Drawbacks of these approaches have been high costs as well as the ability to preserve a resistance adjustment over time, particularly with environmental exposure, and particularly using mechanical arrangements such as potentiometers and rheostats. In addition, resistance adjustment arrangements such as fuse-clearing, which can be cost effective in some applications, only accommodate a one-time adjustment or an adjustment that can only be repeated in one direction such as an adjustment that only increases resistance as fuses are cleared.

Thus what is required is a technique for generating an accurate reference current that is midway between a programmed and an unprogrammed MRAM cell current, and that is not substantially affected by a failure or a performance variation of an individual MRAM reference current cell. In addition, a trimmable resistor is required that can be integrated onto the same die as an integrated circuit, that can be repeatedly and reliably set to a desired resistance value, and that can retain the desired resistance value independently of the application of power to the circuit.

### SUMMARY OF THE INVENTION

In one aspect, the present invention relates to the need to provide a memory device with high reliability and that is tolerant of ordinary manufacturing process variations without compromising device design margins. The present invention further relates to providing a memory device employing magnetic memory technology. Preferably, the present invention relates to magnetic memory technology in which the resistance of a memory device that is programmed to store a “0” (“unprogrammed”) and the resistance of a device that is programmed to store a “1” (“programmed”) does not change by more than a factor of two. The present invention further relates to providing an MRAM memory device employing MTJs. In a further aspect, the present invention relates to the utilization of the resistance characteristics of MTJ devices, including devices based on GMR or another mechanism in which a resistance is dependent on the direction of polarization of a free magnetic layer with respect to a fixed magnetic layer, that can exhibit at least two resistance values dependent on the magnetization polarity of two magnetic layers, and that can be coupled in arrays to increase device reliability or to provide fine adjustment of a circuit resistance. The present invention further relates to providing sufficiently redundant circuit elements that can source a reference cell current whereby a failure of one or more circuit elements does not result in a memory device failure. Co-pending U.S. patent application Ser. No. 10/326,367 (Attorney Docket 2002 P 50075 US), which is incorporated herein by reference as if included in its entirety, is directed towards an MRAM memory device employing one or two reference cells to source an average reference current for sensing the unknown programming state of an MRAM memory cell. In response, the preferred embodiment provides more accurate current-sourcing capability, tolerates individual component failures or parameter drift, and substantially desensitizes device performance to process variations such as due to manufacturing tolerances or operating temperature. Thereby the design and efficient manufacture of reliable and low cost MTJ memory devices is enabled.

In addition, the present invention relates to the need to provide a stable, non-volatile adjustable resistor that can be repeatedly trimmed to a desired resistance value, or to a resistor with a tapped connection that can be repeatedly adjusted to an alternative resistance ratio. These adjustable resistor configurations can also be arranged without a repeatable adjustment option. There is a further need for the adjusted value of resistance to be substantially independent of a failure of one MTJ cell.

Embodiments of the present invention achieve technical advantages as a reference current source that is particularly useful in sensing current in a memory cell such as a resistive memory device to determine its programmed state. A limiting factor often preventing the reliable determination of the programmed state of a memory device is the accuracy of a reference current source coupled to a current comparator in the memory cell state sensing circuit. A practical MRAM memory device includes a large number of memory cells that must be designed with extremely small features to provide competitively a large amount of memory in a small die area. The extremely small feature sizes that are required and their distribution over the area of the die introduce inherent reliability and yield issues and the associated tight design margins that must be considered. Thus, there is a need for sufficient circuit redundancy in the reference current source to enable assessing reliably the unknown programmed state of individual memory cells, particularly in view of the limited change in device resistance between programmed and unprogrammed states, such as a device in which the resistance of a memory device that is programmed to store a “0” (“unprogrammed”) and the resistance of a device that is programmed to store a “1” (“programmed”) does not change by more than a factor of two. Prior art approaches using a small number of cells such as two or four cells do not provide circuit margins tolerant of a single cell failure or parameter drift.

In an embodiment of the present invention, a large number of memory cells are employed to source a reference current by summing individual reference cell currents and scaling the summed current to a required current level for comparison with current in a memory cell to be sensed. Preferably, more than four cells are employed to provide a source for the reference current, and, preferably, a current mirror is included to scale the summed reference cell currents. Preferably, the memory cells are MTJ memory cells.

In accordance with another preferred embodiment of the present invention a large number of reference memory cells are coupled in an array and the resistance of the array is employed to configure a reference current source. Some of the reference memory cells coupled in the array are unprogrammed, i.e., they are set to store a logic 0, and some are programmed, i.e., they are set to store a logic 1, wherein the resistance of each memory cell is dependent on its programmed state. Preferably, more than four memory cells are employed to form the array configured to source the reference current. The reference current from the reference current source may be scaled for comparison with the current in a memory cell to be sensed. Preferably, a current mirror is included to scale the reference current.

In accordance with another preferred embodiment of the present invention a magnetic random access memory device is configured employing more than four memory cells in an array so as to provide an array resistance, and a reference current is sourced depending on the array resistance. Each memory cell conducts a current dependent on its resistance and the reference current source coupled to the array is configured to produce the reference current. The reference current so produced is preferably the average current of a memory cell programmed to store a logic 0 (or “unprogrammed”) and the current of a memory cell programmed to store a logic 1. The reference current so produced may be scaled from the average current of a memory cell programmed to store a logic 0 and the current of a memory cell programmed to store a logic 1. Preferably, a current mirror is included to scale the reference current, and preferably, the memory cells are MTJ memory cells.

Another embodiment of the present invention is a method of sourcing a reference current by employing a large number of memory cells, each memory cell conducting a current depending on its programmed state, summing the individual memory cell currents, and scaling the summed current to a required current level to produce an average current positioned midway between the current of a MTJ memory cell programmed to store a logic 0 and a memory cell programmed to store a logic 1. Preferably, more than four cells are employed to provide a reliable source for the reference current. The method preferably includes scaling the summed current with a current mirror, and preferably, the method includes configuring the memory cells with MTJs.

The method may be used, for example, to sense current from an MTJ memory cell of a memory device such as the one shown in FIG. 1 to determine its programmed logic state.

A further embodiment of the present invention is an array of MTJs configured to provide an adjustable resistance between two array nodes. Each MTJ in the array has a junction area, and at least one MTJ is coupled to at least one of the nodes of the array. The array of MTJs may include series and/or parallel circuit arrangements of a plurality of MTJs to provide for adjustment of the resistance between the two array nodes, or may include only one MTJ. In general, the resistance of an MTJ depends on its junction area and the geometry of its several constituent layers. In a preferred embodiment at least two MTJs in the array have different junction areas. In a further preferred embodiment, the MTJs are arranged in close proximity to at least one current programming trace (conductor) that is configured to magnetize a free magnetic layer of at least one MTJ cell with a polarity that can be set in the same or opposite direction as the magnetic direction of a fixed magnetic layer in the MTJ cell. In a preferred embodiment the resistance of the MTJ cells depends on the direction of magnetic polarity of the free layers with respect to the direction of polarity of the fixed layers. A further embodiment of the present invention provides multiple current programming conductors configured to selectively magnetize free magnetic layers in selected MTJ cells with magnetic polarities that are in the same or opposite direction as the magnetic polarities of fixed magnetic layers in the selected MTJ cells, thereby altering the resistance of the MTJ array. In a further embodiment of the present invention the array includes at least one MTJ and at least one current programming conductor. In a further embodiment of the present invention the array is configured with a tap coupled to a third array node. In a further embodiment of the present invention devices dependent on the giant magnetoresistance effect or another effect in which a resistance is dependent on a magnetized direction are substituted for the MTJs in the array. In a further embodiment a sufficient number of MTJ cells is included in the array so that the failure of one MTJ cell does not substantially affect the adjusted value of resistance. In a further embodiment the number of MTJ cells is greater than four.

Another embodiment of the present invention is a method of configuring MTJs into an array to provide an adjustable array resistance between two array nodes, wherein each MTJ has a junction area, and at least one MTJ is coupled to at least one of the nodes of the array. The method further includes providing an array of a plurality of MTJs using series and/or parallel circuit arrangements to provide for adjustment of the array resistance. The method further includes providing only one MTJ in the array. The method includes configuring the MTJs so that their resistance depends on the MTJ junction areas and the geometry of the several MTJ constituent layers. In a preferred embodiment the method further includes providing at least two MTJs in the array with different junction areas. In a preferred embodiment, the method further includes arranging the MTJs in close proximity to at least one current programming trace (conductor) and configuring that trace to magnetize a free magnetic layer of at least one MTJ cell with a polarity that can be set in the same or opposite direction as the magnetic direction of a fixed magnetic layer in the MTJ cell. In a preferred embodiment the method includes configuring the MTJ cells so that their resistance depends on the direction of magnetic polarity of the free layers with respect to the direction of polarity of the fixed layers. In a further embodiment of the present invention the method includes providing multiple current programming conductors configured to selectively magnetize free magnetic layers in selected MTJ cells with magnetic polarities that are in the same or opposite direction as the magnetic polarities of fixed magnetic layers in the selected MTJ cells, thereby altering the resistance of the MTJ array. In a further embodiment of the present invention the method includes configuring the array with at least one MTJ and at least one current programming conductor. In a further embodiment of the present invention the method includes configuring the array with a tap coupled to a third array node. In a further embodiment of the present invention the method includes substituting devices dependent on the giant magnetoresistance effect or another effect in which a resistance is dependent on a magnetized direction for the MTJs in the array. In a further embodiment the method includes providing a sufficient number of MTJ cells in the array so that failure of one MTJ cell does not substantially affect the adjusted value of array resistance. In a further embodiment the method includes providing more than four MTJ cells in the array.

In the circuit descriptions herein, a transistor may be configured as multiple transistors coupled in parallel, or vice versa, without departing from the scope of the present invention.

Embodiments of the present invention including the methods as described herein may be configured with various resistive technologies to form memory cells. Other applications of the present invention requiring an accurate or reliable current source or a resistance that may be configured with resistive circuit elements that may exhibit component-to-component variations or whose operation may depend critically on the operation of a particular resistive circuit element can benefit from the described techniques. In particular, other memory technologies such as the giant magnetoresistive effect (GMR) that depend on a resistance change to indicate a logic state can directly utilize the present invention. The invention can also be used in other applications requiring a precise resistor or a resistor whose imperfect reliability may unacceptably affect the operation of a system element.

Embodiments of the present invention achieve technical advantages as a reference current source including a memory device including the reference current source. Advantages of embodiments of the present invention include increased performance and reliability in reading information stored in a memory device.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 shows a perspective view of an MTJ stack;

FIG. 2 shows a cross-sectional view of an MRAM memory device having a select FET;

FIG. 3 is a schematic diagram of a memory cell of the memory device shown in FIG. 2;

FIG. 4a is a schematic of an MRAM cell current sensing circuit that averages the current of two reference cells;

FIG. 4b is a schematic of an array of memory cells and two reference cells coupled to a current sensing circuit;

FIG. 5 shows a current sense amplifier that includes a voltage comparator, bitline clamping devices, and an illustrative current mirror for comparing a memory cell current to a reference current;

FIG. 6a shows four resistors coupled in a series-parallel arrangement to produce a circuit with an equivalent resistance at the terminals N1 and N2;

FIG. 6b shows four sub-circuits of four resistors each coupled in a series-parallel arrangement to produce a circuit with an equivalent resistance at the terminals N11 and N12;

FIG. 7 shows an exemplary array of sixteen resistors coupled in a series-parallel arrangement to produce an equivalent resistance;

FIG. 8 shows an exemplary array of sixteen MTJ cells coupled in a series-parallel arrangement to bit lines to produce an equivalent resistance that is the average of MTJ cell resistance programmed in the 0 and 1 logic states;

FIG. 9a illustrates an array of MTJ memory cells coupled to a current comparator and a plurality of MTJ memory cells coupled to form a reference current source;

FIG. 9b illustrates a current scaling circuit that can be used in conjunction with the reference current source illustrated on FIG. 9a; and

FIG. 10 illustrates an array of tunneling magnetic junctions coupled in a series arrangement with associated programming conductors.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

Embodiments of the present invention will be described with respect to preferred embodiments in a specific context, namely a FET MRAM device including a reference current source. The invention may also be applied, however, to resistive memory devices and other memory devices that include a current sense amplifier and a reference current source to detect the resistive state of memory cells. The current sense amplifier and the reference current source are also applicable in other applications where an unknown current is compared to a reference current in order to read or sense the unknown current.

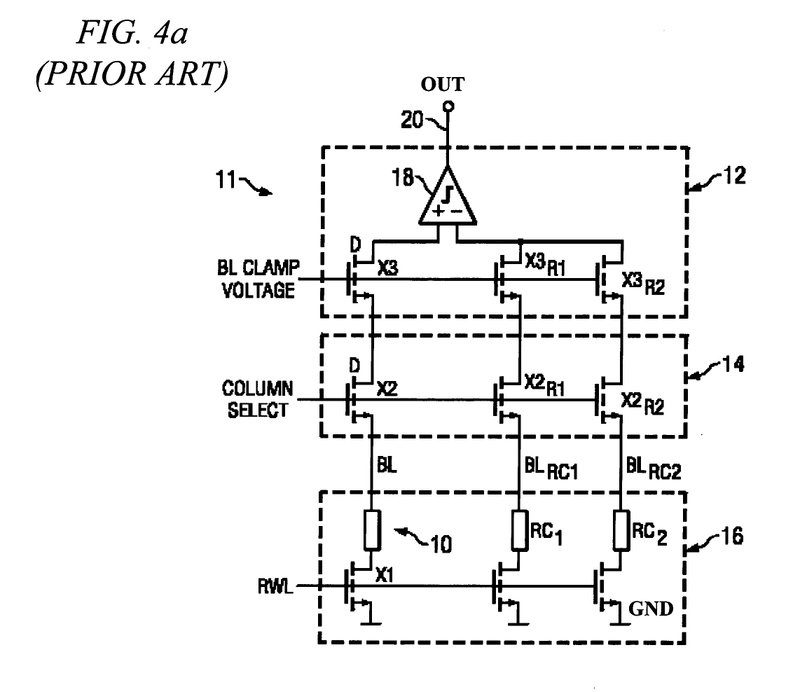

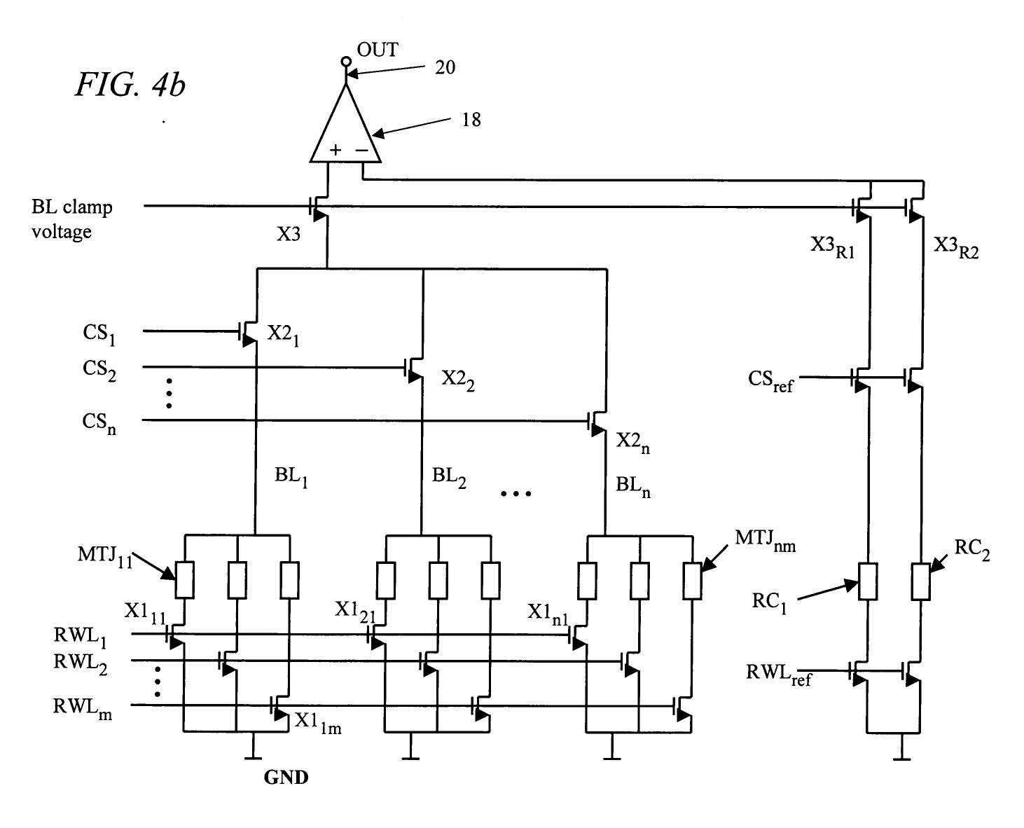

In resistive memory devices such as MRAMs, current sensing circuits including a reference current source may be used to detect the logical state of a memory cell based on cell resistance. A current sense amplifier scheme 11 is shown in the prior art drawing of FIG. 4a. Shown is an example for a current sensing scheme 11 for a 1T1MTJ memory cell using averaging of the two reference cells RC₁ and RC₂ to produce a reference current at the inverting input of the current sense amplifier 12. The current sensing scheme 11 comprises a current sense amplifier 12 and a column selector 14 coupled to a memory array 16. The FETs illustrated on FIG. 4a are N-channel devices.

Only one memory cell 10 is shown; however, there may be hundreds or thousands or more memory cells in the array 16 to form a bulk memory device. The reference cells RC₁ and RC₂ preferably reside in the array with the memory cells 10, but the reference cells RC₁ and RC₂ may alternatively reside in another array 16, for example. Reference cell RC₁ may comprise a cell programmed as a logic 1, and reference cell RC₂ may comprise a cell programmed as a logic 0, for example. Each bitline BL containing a memory cell 10 is connected to at least one column select transistor X2 of the column selector 14. The column selector 14 is connected to the sense amplifier 12. The bitline clamp transistor X3, a source follower with its gate coupled to the bitline (BL) clamp voltage, is coupled to a multiplexer (not shown) that is coupled to a plurality of other memory cells, each via a column select transistor (also not shown). Cell 10, RC₁ and RC₂ are located on bitlines selected by the column selector 14. These cells are shown as examples for cells on the bitlines. Since the resistance of the memory cell 10 is preferably substantially greater than the ON resistance of the series FET switches such as source follower X3, source follower X3 effectively clamps the memory cell voltage to the BL clamp voltage minus approximately its FET threshold voltage. Memory cell voltage during a read operation is typically about 200-300 mV for an MRAM operating from a 1.8 V bias voltage source (not shown), but may be lower or higher in other applications.

As current sensing is used in FIG. 4a, the selected bitlines are kept at a constant potential by bitline clamping transistors X3 during the read operation. The current comparator 18 compares the currents of the selected memory cell 10 with the averaged current of reference cells RC₁ and RC₂, with current scaling as required to form the averaged current. The level of the reference cell current is arranged to produce the approximate midpoint between the current of a selected cell with a logic “0” state and a selected cell with a logic “1” state, in MRAM applications. Alternatively, the current sense amplifier 12 may use only one reference cell, not shown, in other applications.

A read wordline RWL is coupled to the gate of the select transistor X1 of the selected cell 10. If the read wordline RWL is activated, then all of the select transistors X1 in that row of the memory array 16 are switched on. The column select transistor X2 of the column selector 14 is used to select the correct bitline BL (e.g., the column of the selected memory cell 10). The column selector 14 switches the bitline BL of the selected cell to the direction of the sense amplifier 12. The current sense amplifier 12 reads the resistive state of the selected cell 10 by measuring the current. The current sense amplifier 12 comprises a current comparator 18 coupled to transistor X3 and transistors X3_{R1} and X3_{R2} of the reference paths for reference cells RC₁ and RC₂. The current sense amplifier 12 maintains a constant bitline BL voltage during a read operation, using the source-follower clamping transistors X3, X3_{R1} and X3_{R2} that are coupled to the signal “BL clamp voltage.” The current comparator 18 compares the current through transistor X3 of the selected cell 10 with the average of the currents through X3_{R1} and X3_{R2} of the reference cells, to determine the resistive state of selected cell 10, which information is output (indicated by “OUT”) as a digital or logic “1” or “0” at node 20 of the current sense amplifier 12.

The current-sensing scheme 11 shown in FIG. 4a is disadvantageous in that the performance of an entire array of memory cells is dependent on the accuracy of the average current produced by the two reference cells RC₁ and RC₂. A failure of either reference cell, including a change beyond a certain level in a reference cell current, results in an associated portion of a memory cell array becoming inoperative, which may include a substantial number of memory cells.

Two bitlines BL_{RC1} and BL_{RC2} for the two reference cells RC₁ and RC₂ and column selector switches X2_{R1}, X2_{R2} are connected to the right side (the inverting input) of the comparator 18, while one bitline and a large number of column selector switches X2 are connected to the left side (the non-inverting input) of the current comparator 18 of the current sense amplifier 12. For example, there may be one out of 64 bitlines of memory cells 10 coupled to the non-inverting input of the current comparator 18, and two bitlines for reference cells coupled to the inverting input of the current comparator 18. Because of this asymmetry, the capacitive load of the sensing path at the non-inverting input of the current comparator 18 is much different from the capacitive load of the reference path at the inverting input of the current comparator 18. The capacitive load comprises capacitance of the switching transistors X3, X3_{R1} and X3_{R2}, and the metal lines capacitively loaded by the memory cells, e.g., the bitlines BL. Techniques to provide equal capacitive loading of the inputs to the current comparator 18 and thereby to achieve minimal logical state sensing times are described in co-pending U.S. patent application Ser. No. 10/937,155 (Attorney Docket No. 2004 P 50911), which is referenced and included in its entirety herein.

Referring now to FIG. 4b, illustrated is an array of memory cells MTJ₁₁ . . . MTJₙₘ to form an MRAM memory device in accordance with an embodiment of the present invention. Components that are the same as those illustrated on FIG. 4a will not be re-described in the interest of brevity. The current comparator 18 includes a non-inverting and an inverting input, and an output node 20 that indicates a logic state of a selected memory cell. Source followers X3, X3_{R1}, and X3_{R2} clamp the voltage of the selected memory cell and the voltage of the two reference cells RC₁ and RC₂.

The memory cell to be sensed is determined by a memory cell address supplied from an external source (not shown) that is decoded to enable one of column select signals CS₁, . . . . CSₙ and one of read wordline signals RWL₁, . . . , RWLₘ. The switches RWL_{ref} are included to provide symmetry in the circuit for the reference cells RC₁ and RC₂. The enabled column select signal in turn selects one of bitlines BL₁, . . . , BLₙ. The plurality of wordlines may be physically arranged in parallel proximate one side of the memory cells. The plurality of bitlines may also be physically arranged in parallel, and proximate another side of the memory cells. Correspondingly, one of transistors X2₁, . . . , X2ₙ and one of transistors X1₁₁, . . . , X1ₙ₁ are enabled to conduct, selecting thereby a particular memory cell to be sensed. Logic circuits to convert a memory cell address to a particular column select signal and a particular read wordline signal are well known in the art and will not be described further.

A current sense amplifier including the current comparator 18, the column selector including switches CS₁, . . . CSₙ, and switches CS_{ref}, and the clamping circuit including source followers X3, X3_{R1}, and X3_{R2} form a current sensing circuit as described hereinabove with reference to FIG. 4a. Thus, FIG. 4b illustrates an arrangement to sense a selected memory cell in an array of memory cells for comparison with the state of two reference cells using averaging of currents of the two reference cells RC₁ and RC₂ to produce a reference current at the inverting input of the current comparator 18.

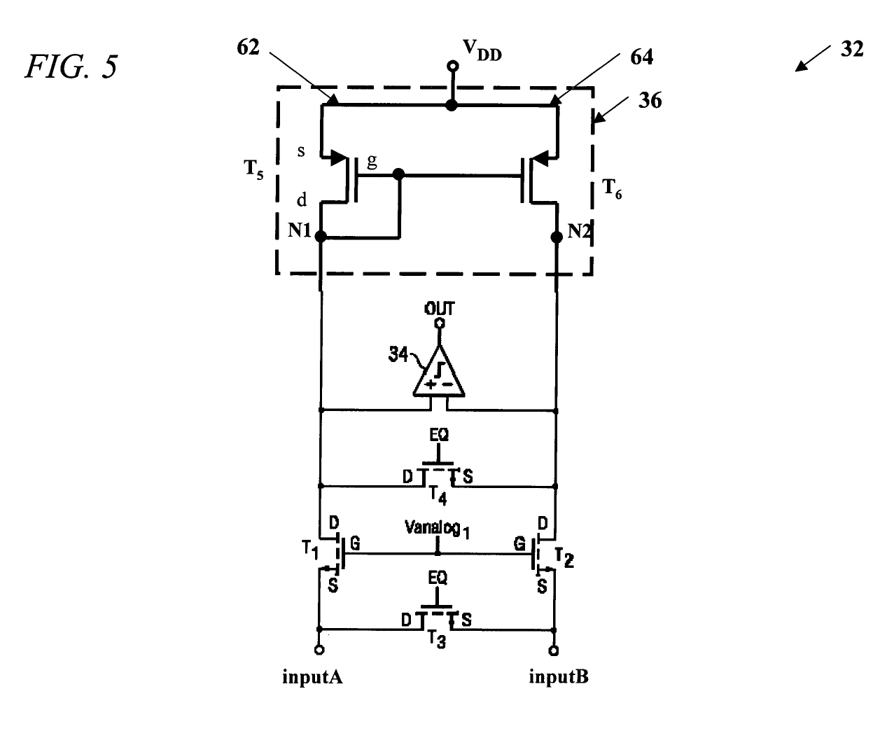

Referring now to FIG. 5, illustrated is a current sense amplifier 32 in accordance with an embodiment of the present invention that includes a voltage comparator 34. The current sense amplifier is configured to compare input currents coupled to inputs inputA and inputB. The drains of bitline clamping devices T₁ and T₂, which preferably comprise transistors, are coupled to the non-inverting and inverting inputs, respectively, of the voltage comparator 34. The sources of transistors T₁ and T₂ are connected to a first input signal node inputA and a second input signal node inputB, respectively, as shown. Assume that inputB is connected to the selected memory cell by a column selector signal (signal COLUMN SELECT in FIG. 4a, or signals CS₁, CS₂, . . . ,CSₙ in FIG. 4b), and that inputA is connected to reference cells producing an average mid-current reading of a “0” and “1” logic memory state. The reference cell current is input, for example, at inputA and is mirrored from transistor T₅, and creates a drain-source voltage at transistor T₅. Alternatively, inputA may be connected to a memory cell storing the opposite logic state of the selected memory cell. Clamping transistors T₁ and T₂ as illustrated on FIG. 5 are N-channel source followers, although other circuit arrangements and other transistor types may be used to clamp a memory cell voltage. The gates of transistors T₁ and T₂ are connected to a reference voltage Vanalog₁ that is preferably configured to provide a bitline clamp voltage as described hereinabove with reference to FIG. 4a. Reference voltage Vanalog₁ (corresponding to “BL clamp voltage” on FIG. 4a) may comprise a voltage level of about 0.7 volts to produce a memory cell voltage of about 200-300 mV, for example, considering FET threshold voltage, although reference voltage Vanalog₁ may alternatively comprise other voltage levels.

The current sense amplifier 32 in FIG. 5 may include optional transistor switches T₃ and T₄, which function as voltage equalizing devices. For example, the source of transistor T₃ may be coupled to signal inputB, the drain of transistor T₃ may be coupled to signal inputA, the source of transistor T₄ may be coupled to the inverting input of the voltage comparator 34, and the drain of transistor T₄ may be coupled to the non-inverting input of the voltage comparator 34. The gates of transistors T₃ and T₄ are coupled to an equalization signal EQ. Before a read operation is initiated, transistors T₃ and T₄ are activated to ensure that the input signal nodes, inputA and inputB, are at the same potential (i.e., equalized), and also to ensure that the inputs of the comparator 34 are equalized at the same potential. Transistors T₃ and T₄ are turned off after a short delay after the bitlines are connected and the memory cells are ready to be read. Connecting bitlines ordinarily causes some transient disturbance in the circuit.

Advantageously, the current sense amplifier 32 includes a current mirror 36 preferably comprised of P-channel transistors with drains coupled to the inputs of the voltage comparator 34. The current mirror includes a first transistor T₅ coupled between a bias voltage source V_{DD} and clamping device T₁, and a second transistor T₆ coupled between the bias voltage source V_{DD} and clamping device T₂. An exemplary voltage for the bias voltage source V_{DD} is 1.8 volts, but lower (or higher) voltages may be used in future or other designs. The gates of transistors T₅ and T₆ are coupled together and to the drain of transistor T₅. The transistor T₅ is configured as a transistor diode. Transistor T₆ is thus configured as a transistor current source.

In a transistor diode configuration, if the gate of a transistor, e.g., transistor T₅, is connected to the drain, and a current is applied to the drain, then a voltage is developed at the drain, and the transistor exhibits diode-like behavior. A current applied at inputA passes through the drain of transistor T₅, which is connected to the gate of transistor T₅, creating a voltage potential between the drain and source of transistor T₅. There is no ohmic, linear load, as in a resistor; rather, the behavior is somewhat similar to that of a diode, which exhibits a non-linear voltage-current characteristic.

On side 62, the drain-to-source voltage of transistor T₁ is substantially variable in the sense that this voltage difference is essentially “self-adjusting” to make up the difference between the drain voltage of transistor T₅ (at node N1) and the roughly 200-300 mV potential at current-sense input, inputA. However, on side 64, the drain-to-source voltage of transistor T₆, which operates in current saturation with its gate voltage determined by transistor T₅, is greatly dependent on its drain-to-source current that, after an initial transient, must substantially equal the drain-to-source current of transistor T₂. Thus the steady-state drain-to-source current of transistor T₆ is substantially determined by the input current at inputB because transistors T₃ and T₄ are disabled to conduct during the MTJ measurement time. Thus, the unequal cell currents from inputA and inputB are converted to a large voltage difference that is coupled to the inputs of comparator 34, particularly by the drain-to-source voltage of transistor T₆. The voltage comparator 34 senses the substantial voltage difference resulting from the small difference of currents from inputA and inputB.

Thus, if the inputB current is a little higher than the inputA current, a large voltage shift at the inverting input of the voltage comparator 36 is created because no substantial current flows into the input terminals of the voltage comparator 34. If additional current is applied at the drain of a transistor in current saturation, a small shift of this current creates a large shift in the drain-source voltage, resulting in a large voltage amplification. This amplified voltage is sensed by the inverting input of the voltage comparator 34. Thus, a large voltage difference is advantageously created between the inverting and non-inverting inputs of the voltage comparator 34, even when the current difference between inputA and inputB is small.

Preferably, transistors T₅ and T₆ have the same dimensions, the same geometry and the same orientation, and comprise the same type of transistors when equal scaling is required for the input currents, inputA and inputB. Moreover, as is well understood in the art, the currents in a current mirror may be scaled as may be required for a particular circuit design by scaling the areas of the respective transistors to produce a scaled current mirror leg current. Preferably, the operating conditions of both transistors T₅ and T₆ should be similar (or scaled) to achieve ideal (or scaled) current mirroring performance.

Transistors T₅ and T₆ thus amplify the voltage difference at the first and second input, inputA and inputB, of the voltage comparator 34 producing a substantial output voltages at the node “OUT” representing a logic state of the selected memory cell. Thus, small differences in currents can be detected in the sides 62 and 63 of the current sense amplifier due to small changes in memory cell resistance as it depends on the state of the memory cell. Transistors T₅, T₆, T₇ and T₈ preferably comprise PMOS transistors, and alternatively may comprise NMOS transistors, as examples. Optional equalization switches T₃ and T₄ may be included in the current sense amplifier and placed directly at inputA and inputB and at the non-inverting and inverting inputs of the comparator stage 34 of the sense amplifier 32.

Thus, the current sense circuit illustrated in FIG. 5 is configured to apply equal voltages to the memory cells by means of the clamp transistors, thereby avoiding altering the charge of unknown parasitic capacitance external to the current sense amplifier, and to provide high sensitivity to small changes in the sensed resistance of a memory cell by means of a current mirror coupled to the drains of the source follower clamps.

The accuracy of the current mirror 36 illustrated in FIG. 5 may be improved by stacking an additional, optional cascode device in series with transistor T₆. Co-pending U.S. patent application Ser. No. 10/326,367 (the '367 application), as previously referenced and incorporated herein, describes circuit techniques to include a cascode device with the current mirror. A cascode device may be included in the circuit to establish similar operating conditions in the current mirror transistors on both sides thereof, thereby improving its accuracy and capacitive behavior. Thus, a sense amplifier including a cascode device can provide current-sensing speed advantages.

The current sense amplifiers as described above depend for their memory sensing operation on a reference current source that is configured using one or two MTJ cells. It is recognized that a reference current produced to sense an MTJ cell logical memory state must be produced with sufficient accuracy that suitable error margins are maintained for the small changes in MTJ resistance due to the two possible logic states of storing a 0 or a 1, and further, that these error margins also include expected variations in MTJ operating parameters due to manufacturing variations as well as MTJ operating voltage variations. Thus, if an MTJ cell configured to provide a reference current fails or otherwise provides an altered cell resistance, then the entire associated memory segment that is sensed with this reference current cannot be reliably sensed and, correspondingly, the entire associated memory segment will also appear to have failed.

A reference current source, configured in accordance with the present invention to provide improved reference current accuracy, improved reliability, and improved immunity to manufacturing variations, includes a large number of reference cells, more than four, that are collectively combined to produce a reference current output. Preferably, 64 or more reference cells are combined. The reference current source may be configured using a series-parallel combination of MTJ cells, or, alternatively, may be configured by combining the outputs of more than four individual current sources, wherein each current source includes a different MTJ cell.

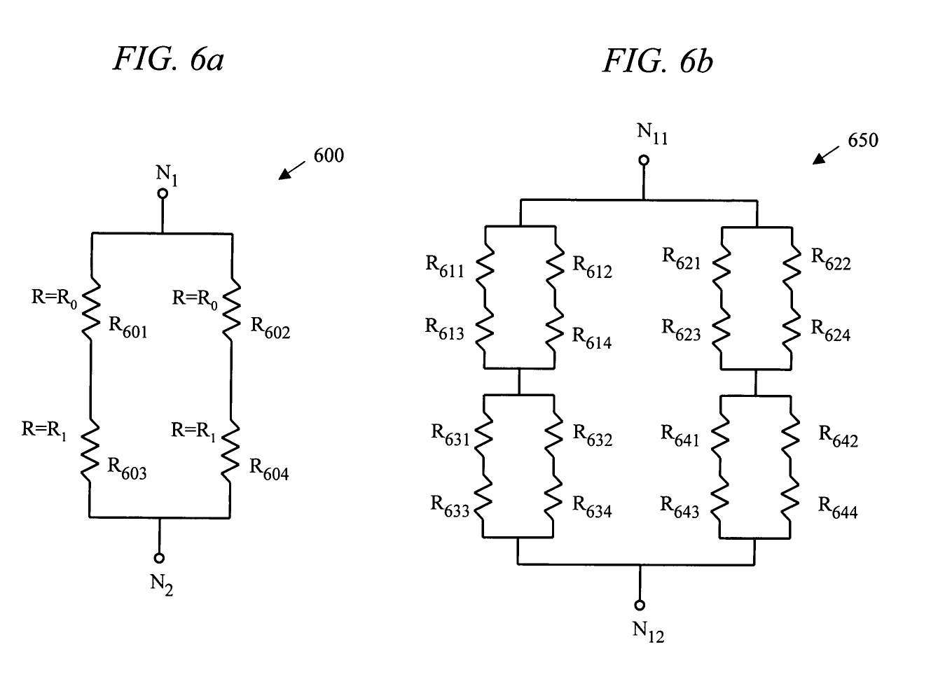

In accordance with the present invention, circuit components are arranged in a network so that the terminal properties of the network are relatively insensitive to a change in value of an individual component. Shown on FIG. 6a is a resistor network 600 with terminals N₁ and N₂ configured with four resistors R₆₀₁, R₆₀₂, . . . , R₆₀₄ with resistance values R₀, R₀, R₁, and R₁; these resistance values correspond to the ideal resistances of MTJ memory cells programmed with logic states 0, 0, 1, and 1, respectively. The resistance of the network 600 at terminals N₁ and N₂ can be readily shown to be the average of the resistances R₀ and R₁, i.e., (R₀+R₁)/2. If a single resistor is used to set the current produced by a reference current source, there is a one-for-one effect of a change of the resistance of the resistor on the output current from the reference current, i.e., a 1% change in resistance results in a 1% change in current. However, for the resistor network 600 the one-for-one effect is reduced approximately by a factor of four, i.e., a 1% change in the resistance of one resistor results in a ¼% change in current of a reference current source employing the network 600. It is recognized that the placement order of the four resistors in the network 600 as well as its particular series-parallel configuration can be altered to achieve the same result.

On FIG. 6b a resistor network 650 is shown wherein the four resistors R₆₀₁, R₆₀₂, . . . , R₆₀₄ each have been replaced with a resistor sub-network, such as by the four resistors R₆₁₁, . . . , R₆₁₄, etc., through R₆₄₄. If the resistance of one resistor in the resistor network 650 is changed, the change in resistance at the terminals N₁₁ and N₁₂ is reduced approximately by a factor of 16, i.e., a 1% change in the resistance of one resistor results approximately in a 1/16% change in current of a reference current source employing the network 650. The process of substituting a resistor network for individual resistors can be continued to configure networks with 64, 256, 1024, etc., resistors. Of course, resistor networks can be configured with a number of resistors other than integer powers of 2 as illustrated above, wherein scaling of resistance or other circuit parameters is employed to achieve the same resistance averaging and desensitizing effects. Furthermore, the particular series-parallel configuration of the network can be altered to achieve the same result.

The reduction in sensitivity of the terminal properties of a resistor network such as the resistor network 650 shown on FIG. 6b can be illustrated by considering the effect of a resistor failing shorted, i.e., exhibiting substantially zero resistance. It can be readily shown that the relative change in resistance measured at the end terminals such as N₁₁ and N₁₂ of resistor network 650 for a resistor failing shorted is approximately MR/n where n is the number of resistors in the network and MR is the relative difference between R₀ and R₁, i.e., MR=(R₁−R₀)/R₀. For example, a 64-resistor network exhibits an altered terminal resistance of approximately 0.6% if one resistor fails shorted. Furthermore, the variation in terminal resistance of a resistor network considering the statistical variation of its individual resistors varies inversely as the square root of the number of resistors, and directly as the standard deviation of resistance of individual resistors. Thus, the number of memory cells forming a resistor network for a reference current source that accommodates variation of individual memory cells or even complete failures of individual reference cells can be readily chosen in view of allowable reference current error margins for satisfactory operation of a memory device.

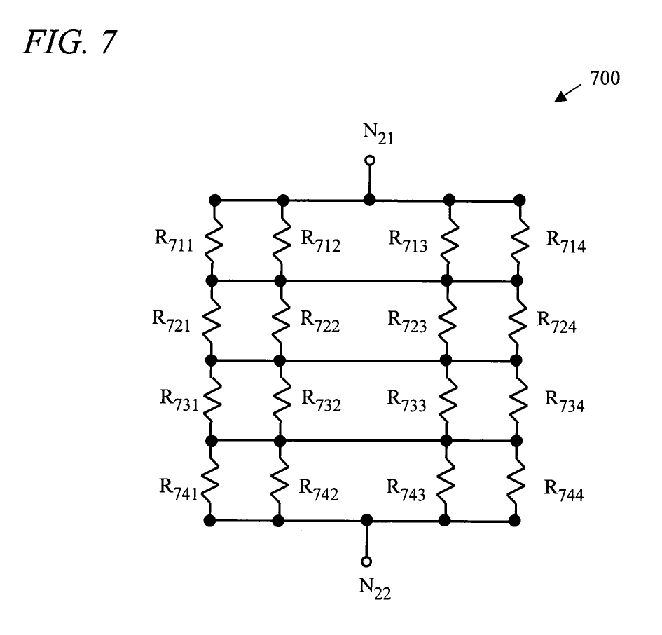

Turning now to FIG. 7, illustrated is an exemplary resistor network 700 formed in accordance with a preferred embodiment of the present invention. The network 700 includes sixteen resistors R₇₁₁, . . . , R₇₄₄ coupled in a series-parallel arrangement wherein the eight resistors R₇₁₁, R₇₁₂, . . . , R₇₁₄ and R₇₃₁, R₇₃₂, . . . , R₇₃₄ each represent the resistance of a memory cell programmed to store a logic 0, and the eight resistors R₇₂₁, R₇₂₂, . . . , R₇₂₄ and R₇₄₁, R₇₄₂, . . . , R₇₄₄ each represent the resistance of a memory cell programmed to store a logic 1. It can be readily shown that the resistance of the network at the terminals N₂₁ and N₂₂ is the average resistance of two memory cells, one programmed to store a logic 0 and one programmed to store a logic 1.

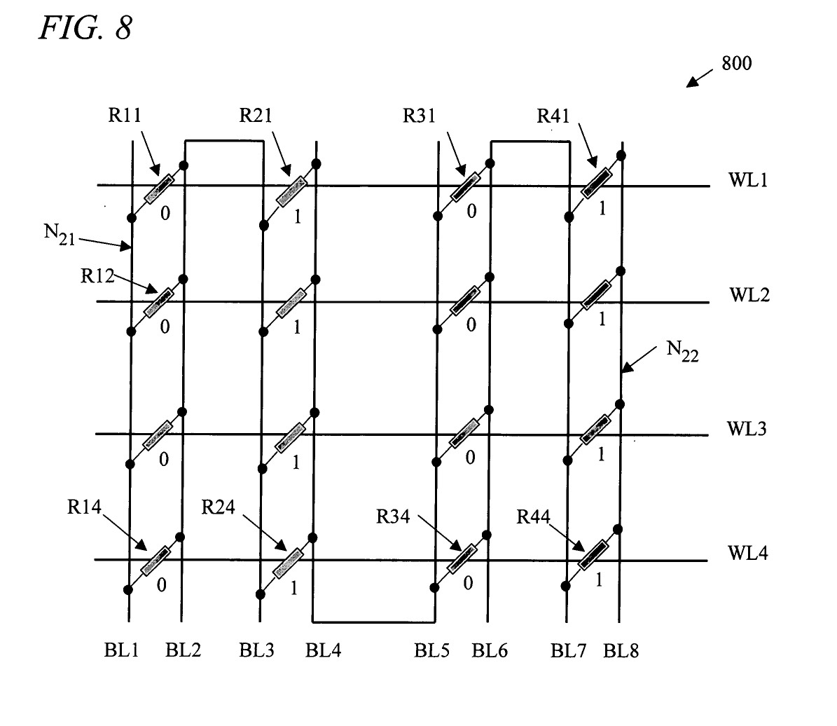

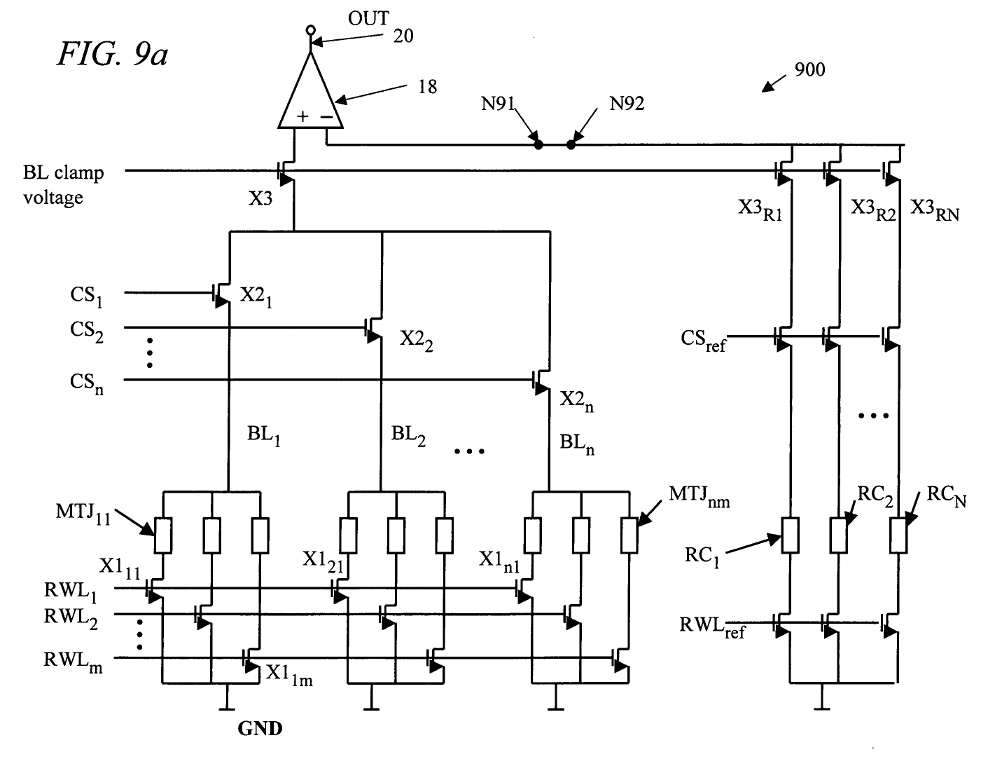

Turning now to FIG. 8, illustrated is an array 800 of MTJ memory cells coupled to bitlines BL1, . . . , BL8 in accordance with a preferred embodiment of the present invention. The memory cells are arranged in a circuit configuration corresponding to the resistors illustrated in FIG. 7, i.e., in this exemplary arrangement resistors R11, . . . , R14 and resistors R31, . . . , R34 represent the resistance of memory cells storing a logic 0, and resistors R21, . . . , R24 and resistors R41, . . . , R44 represent the resistance of memory cells storing a logic 1. The bitlines BL1, . . . , BL8 may be formed on alternating metal levels on a semiconductor die with intermetallic contacts such as TaN, as is well understood in the art, and each MTJ is electrically coupled to two bitlines as shown on the figure. In a preferred embodiment, bitlines BL1, BL4, BL5, and BL8 are formed on one layer, and bitlines BL2, BL3, BL6, and BL7 are formed on another layer.

The resistance at the terminals N₂₁ and N₂₂ of the resistor network formed by the array 800 is the average resistance of two memory cells, one programmed to store a logic 0 and one programmed to store a logic 1. As described above with reference to FIG. 6b, the variation of resistance at the terminals N₂₁ and N₂₂ on FIG. 8 is substantially reduced in view of a possible memory cell failure or a memory cell parameter drift by including a large number of memory cells. The sixteen cells illustrated on FIG. 8 is an exemplary number only, as well as the particular series-parallel circuit configuration. The network illustrated on FIG. 8 can be employed as a reliable and accurate current reference for a current sense amplifier, replacing the individual MTJ cell resistances, such as the resistors RC₁ and/or RC₂ shown on FIGS. 4a and 4b. In this manner the need for circuit adjustment to accommodate manufacturing variations can be substantially reduced or eliminated, thereby reducing end-product cost. As is well known in the art, other series-parallel circuit configurations can be used to reduce the sensitivity of a circuit to one or more component failures or to drift of one or more component parameters. Accordingly, other patterns of 0's and 1's and other interconnection arrangements to provide a network with a large number of cells that provide a reference current source insensitive to the parameters or functional state of an individual cell are herein contemplated and are well within the broad scope of the present invention.

Each open end of a bitline on FIG. 8 is coupled to a current driver (not shown) that can selectively pass a current in either direction along a bitline to “write” the state of the reference memory cells. If each of the two bitlines adjacent to a memory cell carries a current, the associated magnetic fields are superimposed, substantially doubling the magnetic field of a single current-carrying bitline and resulting in a reliable write operation for the memory cells in that column. This field enhancement avoids the “half select” problem that can ordinarily occur during a cell-writing operation for a single selected cell. The design of a write process must account for cell position, cell configuration, and magnetic field variations when a cell is written only from a current-carrying wordline and a single current-carrying bitline. Thus, the half-select error problem ordinarily encountered with individual cells can be avoided by a pattern of writing all cells in a vertical column to the same state, as indicated on FIG. 8, thereby increasing operating margins.

The array structure for producing a reference current shown on FIG. 8 would preferably be placed on the same die as the memory cells that functionally store the memory data, thereby providing temperature tracking a well as matching the parameter variations normally encountered during die manufacture. One may even use a portion of the regular memory cell array to provide closer parameter tracking. Locating the reference current array off-chip is a functional but less preferable arrangement.

An adjustment to the bias voltage source supplying the resistor network 800 may be required to produce an accurate reference cell resistance, recognizing, as previously indicated, that the resistance of a programmed or unprogrammed MRAM cell depends on applied cell voltage. Since many MTJ reference cells are effectively coupled in series, each cell accordingly is supplied with a reduced bias voltage. In addition; the finite resistance of any series switch, for example the series switches X2_{R2} and X3_{R2} on FIG. 4a, also reduces the bias voltage applied to an individual memory cell. Thus, some accommodation may preferably be made, either to the bias voltage, or to the scaling of the reference current so sourced, to account for memory cell voltage differences from the voltage of the data cells being sensed. A method to provide proper reference cell voltage includes scaling transistor switches such as FETs in series with the resistor network 800, coupling their gates in parallel, and controlling the gates of these FETs, preferably with a common signal.

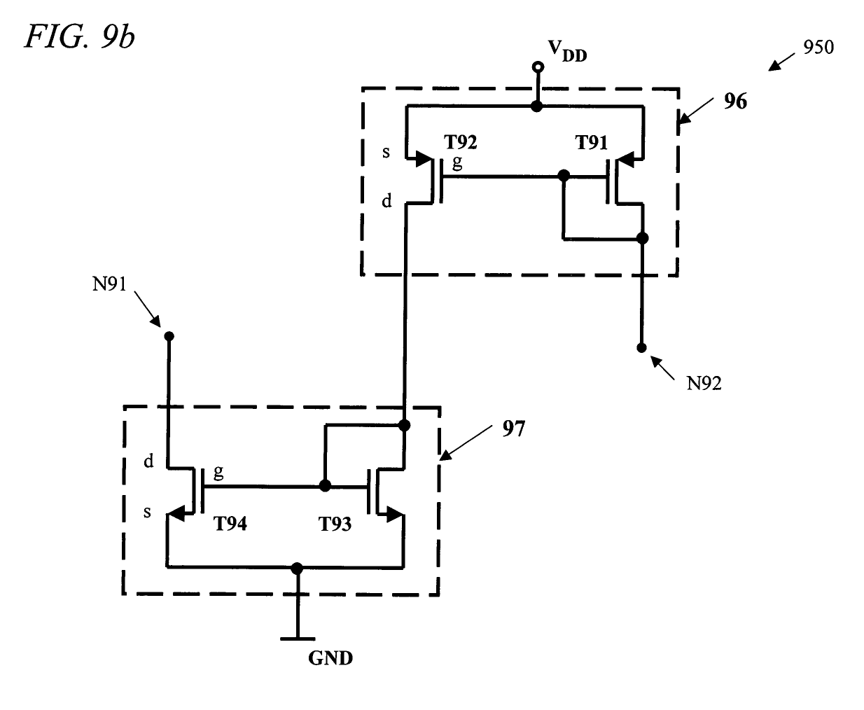

Referring now to FIG. 9a, illustrated is an array of memory cells MTJ₁₁ . . . MTJₙₘ in accordance with an embodiment of the present invention. Components that are the same as those illustrated on FIG. 4b will not be re-described in the interest of brevity. FIG. 9a illustrates an arrangement to sense a selected memory cell in an array of memory cells for comparison with the states of a large number N of reference cells using averaging of currents of the plurality of reference cells RC₁, RC₂, . . . , RC_{N} to produce a reference current at the inverting input of the current comparator 18. The number N of reference cells is greater than four; preferably the number of reference cells is at least 64. A small number of reference cells such as four is inadequate to protect against a reference cell failure or substantial drift of a parameter such as cell resistance. Thus, FIG. 9a illustrates an arrangement to sense a selected memory cell in an array of memory cells for comparison with the state of many reference cells using averaging of their currents by a current summing arrangement to produce a reference current at the inverting input of the current comparator 18.

The current from a number of reference cells may be required to be scaled for comparison with the current of an individual memory cell being sensed, depending on the particular circuit or device configuration. If the reference current is required to be scaled for a particular application, a circuit to scale reference cell current can be formed, for example, by coupling a complementary pair of current mirrors between a bias voltage source, V_{DD}, such as 1.8 volts and ground, GND, as illustrated on FIG. 9b. The current scaling circuit 950 on FIG. 9b includes a P-channel current mirror 96 configured with the P-channel transistors T91 and T92, and an N-channel current mirror 97 configured with the N-channel transistors T93 and T94. The design of current mirrors is well known in the art, and current mirrors can be designed to provide a scaled output current, for example, by scaling the ratio of the areas of the component transistors. Thus, there are two opportunities for current scaling employing the current scaling circuit 950. One is by scaling the ratio of areas of transistors T91 and T92, and the other is by scaling the ratio of areas of transistors T93 and T94. The net current scaling factor for the combination of the two current mirrors is the product of the scaling factor for each current mirror. The circuit nodes N91 and N92 on FIG. 9b are inserted into the circuit on FIG. 9a by opening the circuit path on FIG. 9a between nodes N91 and N92.

Other variations of the techniques described hereinabove may be employed within the broad scope of the present invention to reduce the sensitivity of a reference current source to the parameters or functional state of one or more memory cells. These include but are not limited to configuring a substantial number of current sources, each employing a memory cell storing either a logic 0 or a logic 1, and summing the current-source currents. The current-summing operation can be performed, as is well known in the art, by a current mirror, with the areas of the current mirror transistors scaled to provide an output current midway between a memory cell storing either a logic 0 or a logic 1. Summing operations can also be performed with operational amplifiers, as is well understood in the art.

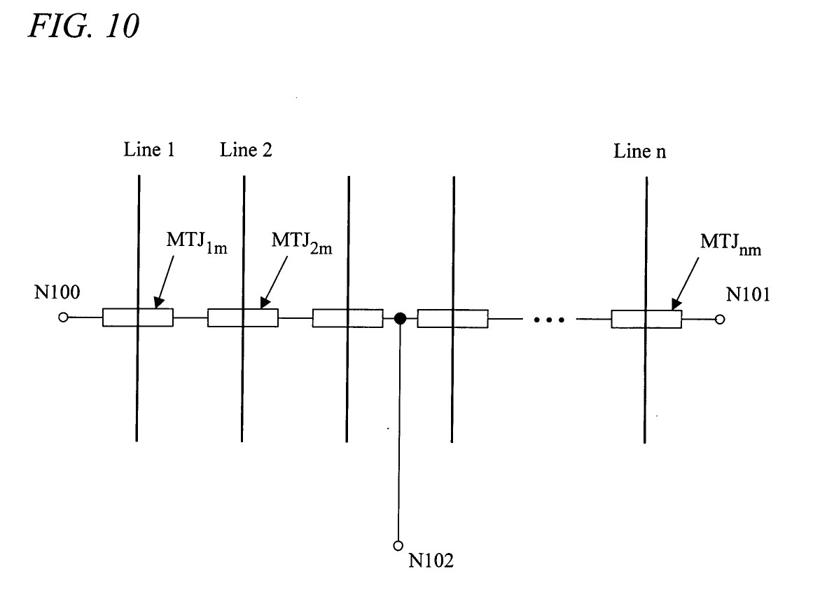

Referring now to FIG. 10, illustrated is an array of MTJ cells with an adjustable resistance in accordance with an embodiment of the present invention. The array is formed by coupling the MTJ cells MTJ₁ₘ, MTJ₂ₘ, . . . , MTJₙₘ in series with nodes N100 and N101. By selectively programming the magnetic polarity of the free magnetic layer of each cell, an adjustable resistance at the nodes N100 and N101 can be produced. The maximum resistance at the nodes N100 and N101 occurs when the magnetic direction of each free layer is oriented in a direction opposite to the magnetic direction of each associated fixed layer. The maximum resistance at the nodes N100 and N101 is the sum of the maximum resistances of the cells in the array. The minimum resistance occurs when the magnetic directions of the free and fixed layers are the same, and is the sum of the minimum resistances of the cells in the array. The step size of resistance is the change in resistance of one cell. Thus, the maximum change in resistance at the nodes N100 and N101 of the order of 20% can be produced, assuming the change in resistance achievable with one cell is 20%. Of course a higher percentage change of the array can be achieved if the design of the MTJs is such that they individually exhibit a higher percentage resistance change.

The areas of the MTJ cells in the array illustrated on FIG. 10 need not be identical. A range of MTJ cell areas may be chosen for the array design to provide a suitable total array resistance as well as suitably fine adjustment granularity. A larger MTJ area generally results in proportionately smaller MTJ resistance. In addition, a suitably large number of MTJs may be included in the array to provide a low voltage across each MTJ or to reduce the sensitivity of the adjusted resistance to the failure of one MTJ cell. Preferably, more than four MTJ cells are included in the array. As the voltage across each MTJ is increased, its resistance generally decreases, as well as the percent change of resistance between the programmed and unprogrammed state. An operating range for MTJs is typically a few millivolts to several hundred millivolts. Lower MTJ voltages, such as 10 millivolts, are generally preferred so as to provide higher percentage change of resistance.

The array of MTJ cells illustrated on FIG. 10 includes an optional node N102. Such a node can be used to form an adjustable, non-volatile voltage divider such as a potentiometer. Since all the MTJs in the array will have a comparable operating temperature, quite accurate resistance tracking of the two sections of the voltage divider with temperature changes and variations across manufacturing lots can be achieved. Generally, the resistance of TMR devices decreases as temperature increases, and the resistance of GMR devices increases as temperature increases. However the resistance ratio in a voltage divider can be reasonably accurate over a range of temperature. The inverse temperature-dependent resistance effects of these devices, including the ordinary increase of resistance of other devices employing metals or semiconductors, provides a design option to compensate for a temperature-dependent resistance by including multiple device technologies in the circuit to provide a resistance, as is well understood in the art.

Although the array of MTJ cells illustrated in FIG. 10 is a series circuit arrangement, other circuit arrangements including parallel arrangements of the MTJ cells and a combination of series and parallel arrangements of the MTJ cells are within the broad scope of the present invention and can be beneficially employed. The series-parallel arrangements of MTJ cells illustrated on FIGS. 6a, 6b, and 7 without limitation are exemplary alternative circuit arrangements. Different circuit configurations can be utilized to provide finer or coarser adjustments to the array resistance as well as the voltage each MTJ junction must sustain. Further, the location of a tap to form a voltage divider, if required, can be placed at any of the internal circuit nodes of MTJ array.

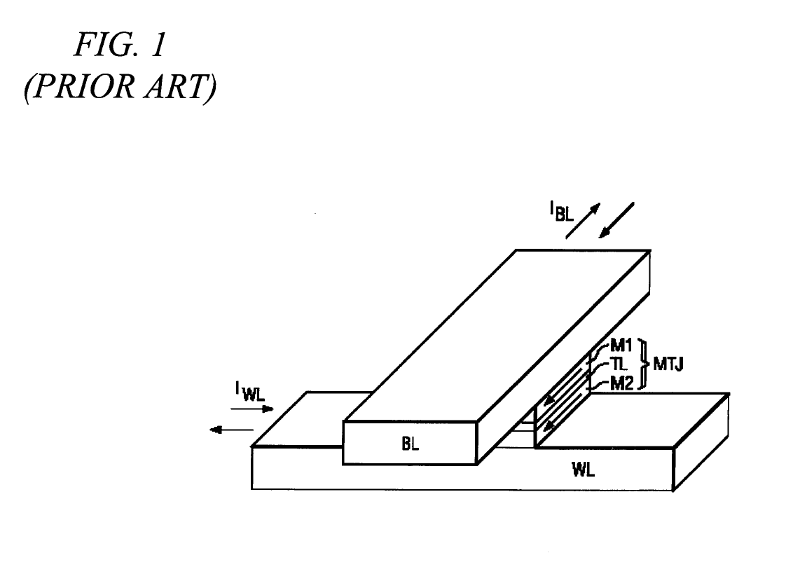

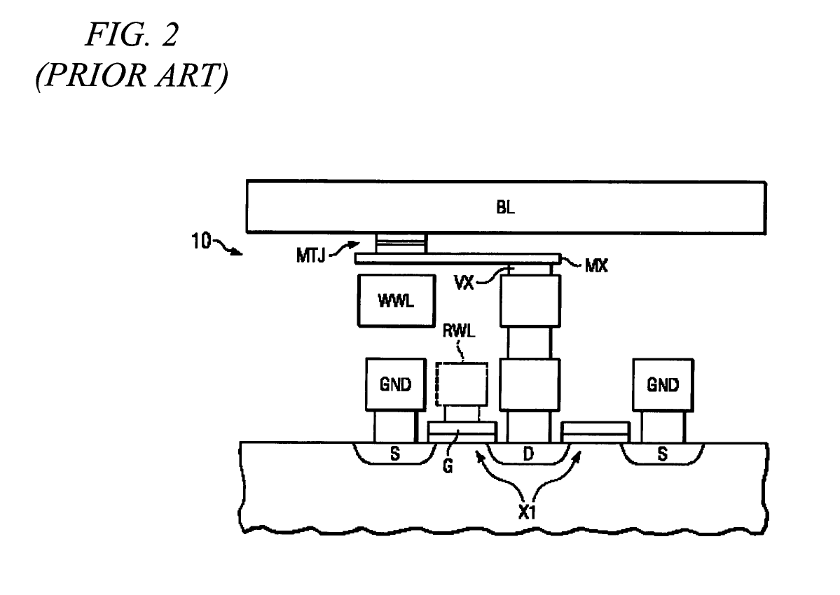

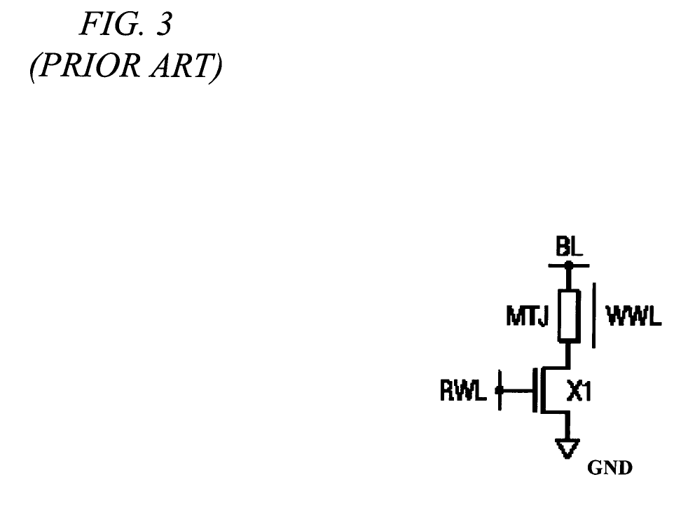

Each MTJ in the array is programmable by providing a suitable current in the associated conductors, Line 1, Line 2, . . . , Line n. As is well understood in the art, the programming current must be sufficient in magnitude and duration to set the direction of magnetization of a free layer without substantially disturbing the magnetic direction of the associated fixed layer. Alternatively, programming of the free layer can be performed with two or more current-carrying conductors such as may be formed by selectively depositing aluminum traces adjacent to the selected cell using photo-etching techniques, as is well understood in the art. Thus, in general, the resistance of the elements of an MTJ array can be programmed using MRAM-like current programming techniques such as described with reference to FIGS. 1, 2, 4a, 4b, 8, 9a, and 10. For example, without limitation, they can be programmed with crossed word and bit lines, or with a single current programming line, or with multiple parallel current programming lines lying above or below the MTJ to generate the critical switching current. In general, the current-carrying programming conductors may lie in a plurality of layers.

Although embodiments of the present invention and its advantages have been described in detail, it should be understood that various changes, substitutions and alterations can be made herein without departing from the spirit and scope of the invention as defined by the appended claims. For example, it will be readily understood by those skilled in the art that the circuits, circuit elements, and current sensing arrangements described herein may be varied while remaining within the scope of the present invention, including other technologies requiring a precision or reliable resistance such as a memory technology using the GMR effect.

Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A current source configured to produce an output current, comprising:
a plurality of more than four resistors, at least one of said resistors programmed to store a logic 0 and at least one of said resistors programmed to store a logic 1, each of said resistors having a resistance representing a logic state, wherein the current source is configured to produce said output current dependent on the resistance of each of said resistors.

2. The current source according to claim 1, wherein said resistors are configured with memory cells, each memory cell having a resistance dependent on its logic state.

3. The current source according to claim 1, wherein said resistors are configured with magnetic memory cells.

4. The current source according to claim 1, wherein said resistors are configured with MTJ memory cells.

5. The current source according to claim 1, wherein the resistance of said resistors programmed to store a logic 0 and the resistance of said resistors programmed to store a logic 1 does not change by more than a factor of two.

6. The current source according to claim 1, wherein said resistors are coupled in an array with an array resistance; and
wherein said current source is coupled to said array to produce said output current dependent on said array resistance.

7. The current source according to claim 2, wherein each memory cell conducts a current dependent on its resistance; and
said current source coupled to said array is configured to produce said output current that is substantially the average current of a memory cell programmed to store a logic 0 and the current of a memory cell programmed to store a logic 1.

8. The current source according to claim 2, wherein said output current is scaled to the average current of a memory cell programmed to store a logic 0 and the current of a memory cell programmed to store a logic 1.

9. The current source according to claim 1, wherein the plurality of resistors includes at least 64 resistors.

10. A current source comprising:
a plurality of more than four memory cells, at least one of said memory cells programmed to store a logic 0 and at least one of said memory cells programmed to store a logic 1, each of said memory cells having a resistance dependent on its logic state and each of said memory cells conducting an memory cell current that is dependent on the resistance of that memory cell; and
a current summing circuit summing said memory cell currents to produce an output current.

11. The current source according to claim 10, wherein said memory cells are magnetic memory cells.

12. The current source according to claim 10, wherein said memory cells are MTJ memory cells.

13. The current source according to claim 10, wherein said output current is scaled from said summed memory cell current.

14. The current source according to claim 10, wherein the resistance of said memory cells programmed to store a logic 0 and the resistance of said memory cells programmed to store a logic 1 does not change by more than a factor of two.

15. A magnetic random access memory device, comprising:
an array of a plurality of memory cells;
selection circuitry coupled to the array configured to select at least one memory cell;
a reference current source coupled to a plurality of more than four other memory cells configured to produce a reference current dependent on the resistance of each of said other memory cells, wherein at least one of said other memory cells is programmed to store a logic 0 and at least one of said other memory cells is programmed to store a logic 1, and each of said memory cells has a resistance dependent on its logic state; and
a current comparator with a first input coupled to receive the reference current, and a second input coupled to the array of the plurality of memory cells to receive current based on the logic state of the at least one selected memory cell.

16. The magnetic random access memory device according to claim 15, wherein said memory cells are magnetic memory cells.

17. The magnetic random access memory device according to claim 15, wherein said memory cells are MTJ memory cells.

18. The magnetic random access memory device according to claim 15, wherein the resistance of said memory cells programmed to store a logic 0 and the resistance of said memory cells programmed to store a logic 1 does not change by more than a factor of two.

19. The magnetic random access memory device according to claim 15, wherein said other memory cells coupled to the reference current source are coupled in a second array with an array resistance; and
said reference current source is coupled to said second array to produce said reference current dependent on said second array resistance.

20. The magnetic random access memory device according to claim 15, wherein each memory cell conducts a current dependent on its resistance; and
said reference current source is coupled to said plurality of more than four other memory cells to produce said reference current that is substantially the average current of a memory cell programmed to store a logic 0 and the current of a memory cell programmed to store a logic 1.

21. The magnetic random access memory device according to claim 15, wherein said reference current is scaled to the average current of a memory cell programmed to store a logic 0 and the current of a memory cell programmed to store a logic 1.

22. The magnetic random access memory device according to claim 15, wherein the plurality of more than four other memory cells configured to produce a reference current includes at least 64 memory cells.

23. A magnetic random access memory device, comprising:
an array of a plurality of memory cells;
selection circuitry coupled to the array configured to select at least one memory cell;
a plurality of more than four other memory cells configured to produce a reference current, wherein at least one of said other memory cells is programmed to store a logic 0 and at least one of said other memory cells is programmed to store a logic 1;
each memory cell has a resistance dependent on its logic state and each is configured to conduct a current dependent on its resistance;
a current summing circuit summing the currents of the other memory cells to produce a reference current; and
a current comparator with a first input coupled to receive the reference current, and a second input coupled to the plurality of memory cells to receive current based on the logic state of the at least one selected memory cell.

24. The magnetic random access memory device according to claim 23, wherein said memory cells are magnetic memory cells.

25. The magnetic random access memory device according to claim 23, wherein said memory cells are MTJ memory cells.

26. The magnetic random access memory device according to claim 23, wherein said reference current is scaled from said summed memory cell current.

27. A method of producing an output current from a current source, comprising:
providing an array that includes at least five memory cells;
programming at least one of said memory cells to store a logic 0;
programming at least a second one of said memory cells to store a logic 1, wherein each of said memory cells has a resistance dependent on its logic state; and
coupling a current source to said array to produce an output current that is dependent on the resistance of each of said memory cells.

28. The method according to claim 27, wherein said memory cells are magnetic memory cells.

29. The method according to claim 27, wherein said memory cells are MTJ memory cells.

30. The method according to claim 27, wherein said array has an array resistance and wherein coupling said current source to said array produces said output current dependent on said array resistance.

31. The method according to claim 27, and further comprising:
coupling said current source to said array to produce said output current that is substantially the average current of a memory cell programmed to store a logic 0 and the current of a memory cell programmed to store a logic 1.

32. The method according to claim 31, and further comprising scaling said output current to the average current of a memory cell programmed to store a logic 0 and a memory cell programmed to store a logic 1.

33. The method according to claim 27, wherein the array that includes at least five memory cells includes at least 64 memory cells.

34. A method of producing an output current from a current source including a current summing circuit, comprising:
providing a plurality of more than four memory cells;
programming at least one of said memory cells to store a logic 0;
programming at least a second one of said memory cells to store a logic 1, each of said memory cells having a resistance dependent on its logic state such that each of said memory cells conducts a memory cell current that is dependent on the resistance of that MTJ memory cell; and
summing said memory cell currents to produce said output current.

35. The method according to claim 34, wherein said memory cells are magnetic memory cells.

36. The method according to claim 34, wherein said memory cells are MTJ memory cells.

37. The method according to claim 34, and further comprising scaling said output current from said summed memory cell current.

38. An adjustable resistor comprising:
a plurality of magnetic memory devices coupled between a first node and a second node so as to form a current path between the first node and the second node;
the magnetic memory devices each having a junction area, the magnetic memory devices each including a free magnetic layer and a fixed magnetic layer, the free magnetic layers programmable in substantially the same or opposite direction as the fixed magnetic layers, wherein the resistance of each magnetic memory device is dependent on the programmed direction of its free magnetic layer; and
a plurality of conductive traces, each conductive trace adjacent to at least one magnetic memory device, each conductive trace configured to program the direction of the free magnetic layer of the at least one adjacent magnetic memory device with a programming current such that a resistance along the current path between the first node and the second node can be varied in accordance with signals provided to the conductive traces.

39. The adjustable resistor according to claim 38, wherein the plurality of magnetic memory devices includes more than four magnetic memory devices.

40. The adjustable resistor according to claim 38, wherein the magnetic memory devices are magnetic tunnel junction (MTJ) devices.

41. The adjustable resistor according to claim 40, wherein the resistance of said MTJ devices depends on the tunneling magnetoresistance effect.

42. The adjustable resistor according to claim 38, and further including a third node between the first node and the second node such that a resistor divider is formed between the first, second and third nodes.

43. The adjustable resistor according to claim 40, wherein the MTJ devices are coupled in a series arrangement.

44. The adjustable resistor according to claim 40, wherein at least two MTJ devices have unequal junction areas.

45. A method of configuring an array of magnetic memory devices to provide an adjustable resistance between two array nodes, the method comprising:
providing a plurality of magnetic memory devices coupled between a first array node and a second array node, each magnetic memory device including a junction area, a free magnetic layer and a fixed magnetic layer, the free magnetic layer being programmable in substantially the same or opposite direction as the fixed magnetic layers, wherein the resistance of each magnetic memory device is dependent on the programmed direction of its free magnetic layer with respect to the programmed direction of its fixed magnetic layer;
providing a plurality of conductive traces, each conductive trace adjacent to at least one magnetic memory device so that the direction of the free magnetic layer of the magnetic memory device can be programmed in substantially the same or opposite direction as the fixed layer with a programming current through the conductive trace; and
programming a resistance between the first array node and the second array node by providing a programming current to selected ones of the magnetic memory devices.

46. The method according to claim 45, wherein providing a plurality of magnetic memory devices comprises providing a plurality of MTJ devices.

47. The method according to claim 45, wherein providing a plurality of magnetic memory devices comprises providing more than four magnetic memory devices.

48. The method according to claim 46, wherein the MTJ devices are configured so that their resistance is dependent on the tunneling magnetoresistance effect.

49. The method according to claim 45, further comprising a third array node between the first array node and the second array node such that a resistor divider is formed by a resistance between the first array node and the third array node and a resistance between the second array node and the third array node.

50. The method according to claim 46, wherein providing a plurality of MTJ devices comprises coupling the plurality of MTJ devices in a series arrangement.

51. The method according to claim 46, wherein providing a plurality of MTJ devices comprises coupling the plurality of MTJ devices in a parallel arrangement.

52. The method according to claim 46, wherein at least two MTJ devices in the plurality of MTJ devices have unequal junction areas.
